(19) United States
(12) Patent Application Publication
(10) Pub. No.: US 2023/0400343 A1
(43) Pub. Date: Dec. 14, 2023

(54) SENSOR LOCATION AND VERIFICATION SYSTEM

(71) Applicant: WATTS REGULATOR CO.

(72) Inventors: Glen Paulus, La Mesa, CA (US); Laurie Conner, Redwood City, CA (US); Matt Barth, San Diego, CA (US)

(21) Appl. No.: 18/208,202

(22) Filed: Jun. 9, 2023

Related U.S. Application Data
(60) Provisional application No. 63/350,924, filed on Jun. 10, 2022.

(51) Int. Cl. G01F 23/80; G01R 33/00; G01R 33/07

(52) U.S. Cl. CPC G01F 23/802; G01R 33/0047; G01R 33/072; G01R 33/0023

(57) ABSTRACT

A water sensor location verification system includes a water sensor configured to generate one or more signals indicative of a presence of water, a sensor locator configured to be coupled to a support surface and configured to be removably coupled to the water sensor to form a sensor/locator pairing, and a pairing verification circuit configured to generate a pairing notification indicative of a status of the sensor/locator pairing. A water sensor configured to be removably coupled to sensor locator to form a sensor/locator pairing includes circuitry to generate one or more signals indicative of water and a pairing verification circuit comprising magnet sensor(s) configured to detect magnet(s) associated with the sensor locator. The paring verification circuit generates a pairing notification indicative of a status of the sensor/locator pairing based on, at least in part, the detection of the magnet(s) and is a normally closed circuit.

### CROSS REFERENCE TO RELATED APPLICATIONS

This application is a U.S. Nonprovisional Application and claims benefits of U.S. Provisional Application 63/350,924 filed 10 Jun. 2022, which is incorporated herein by reference in its entirety.

### TECHNICAL FIELD

The present disclosure is generally directed to sensor location and verification systems and methods, more particularly to systems and methods for securing a wireless sensor within a building and verifying sensor location after removal and reinstallation.

### BACKGROUND INFORMATION

Detecting water leaks as quickly as possible is important in order to minimize damage to a building structure as well as any contents within the building. Currently, there exists systems for not only detecting water leaks, but also identifying the location of the water leak so that preventative action may be taken as quickly as possible. Some of these systems utilize wireless sensors arranged at predetermined locations within the building. As may be appreciated, some installations may include dozens or even hundreds of sensors placed throughout the building. When a wireless sensor detects water, the wireless sensor will emit a signal that ultimately triggers an alarm/notification indicative of the water leak as well as the location of the sensor within the building. Some of the water detection systems can also automatically activate automated shutoff valves to minimize damage to the building and any contents therein. An important feature of these systems is that the location of the sensor within the building is correct. While simply notifying building maintenance personnel of a water leak is useful, knowing the exact location within the building of the sensor that detected the water leak is particularly useful when diagnosing the possible cause and the appropriate remedial action. Moreover, knowing the exact location within the building of the sensor that detected the water leak is particularly useful for systems that take automatic action (e.g., activating automated shutoff valves) otherwise the appropriate automatic action may not be taken.

The water sensors may be secured within a room (e.g., proximate the floor) such they can be easily removed. One known method of removably securing a water sensor within a room includes hook & loop fasteners. Removal of the water sensors may be necessary, for example, to allow the floors to be cleaned without accidentally triggering a false water leak detection. While cleaning an area, maintenance personal may remove several water sensors at the same time. Because the water sensors often all look the same as well as user error, maintenance personal occasionally inadvertently replace the water sensors in the wrong location within the building. When an incorrectly relocated water sensor detects water, the actual location of the sensor will not correspond to the location associated with the water sensor. The location disconnect may cause confusion, reduce remedial action response time, and/or trigger incorrect automatic action.

### BRIEF DESCRIPTION OF THE DRAWINGS

Features and advantages of various embodiments of the claimed subject matter will become apparent as the following Detailed Description proceeds, and upon reference to the Drawings, wherein like numerals designate like parts, and in which:

FIG. 1 is a schematic overview that depicts an illustrative sensor detection system consistent with at least one example of the present disclosure;

FIG. 2 generally illustrates components of the sensor detection system of FIG. 1, in accordance with at least one embodiment described herein;

FIG. 3 generally illustrates a sensor in accordance with at least one embodiment described herein;

FIG. 4 is a top, front, perspective view of an assembled sensor location verification system, in accordance with at least one embodiment described herein;

FIG. 5 is a bottom, rear perspective view of the assembled sensor location verification system of FIG. 4, in accordance with at least one embodiment described herein;

FIG. 6 is an upper perspective view of a sensor locator including a pairing verification circuit, in accordance with at least one embodiment described herein; and

FIG. 7 is a rear view of a sensor including a pairing verification circuit, in accordance with at least one embodiment described herein.

Although the following Detailed Description will proceed with reference being made to illustrative embodiments, many alternatives, modifications, and variations thereof will be apparent to those skilled in the art.

### DETAILED DESCRIPTION

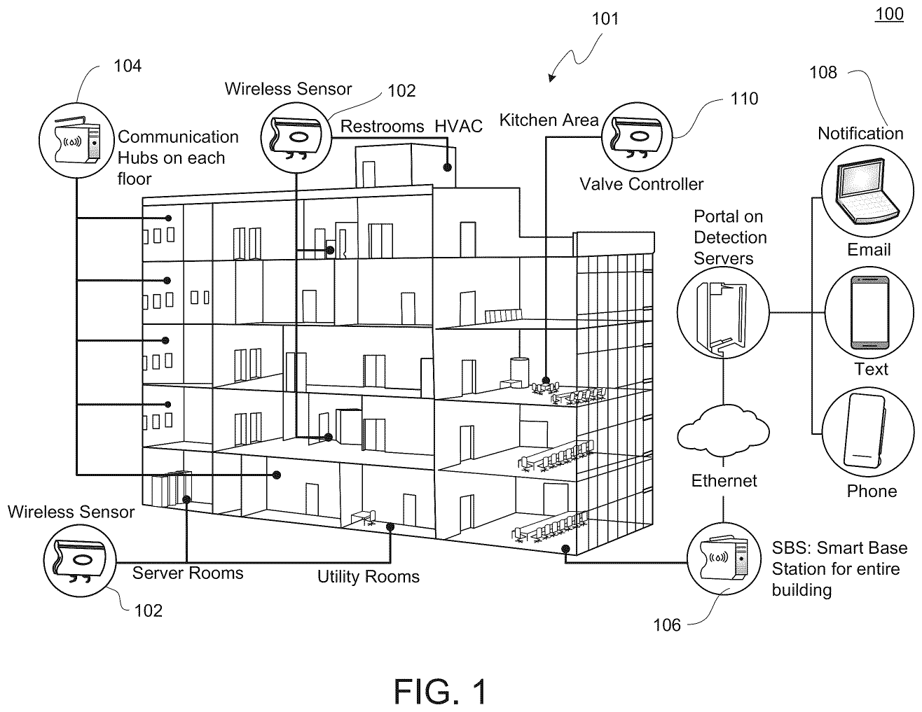

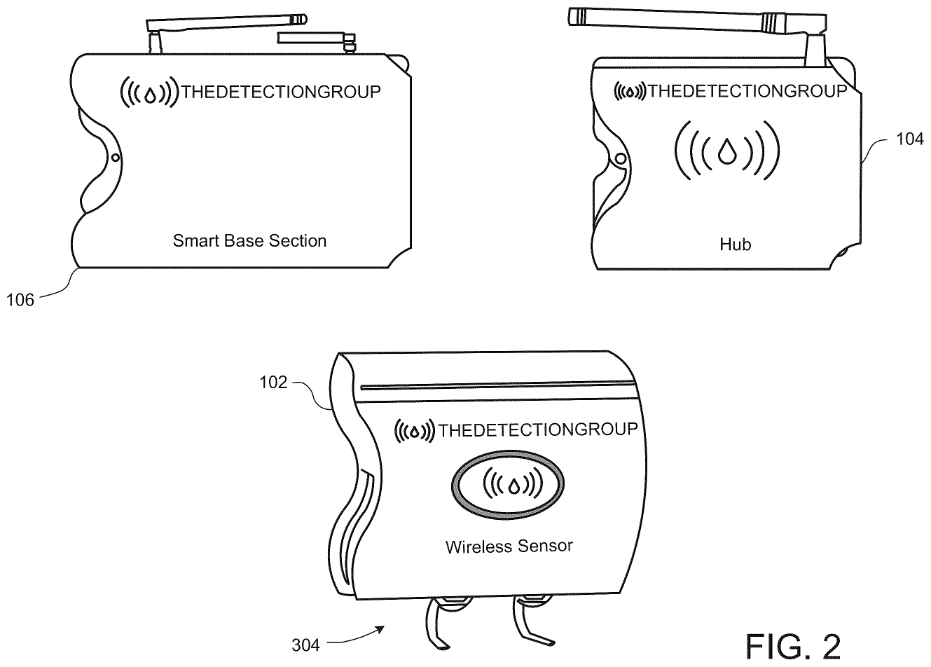

FIG. 1 is a schematic overview that depicts an illustrative sensor detection system 100 consistent with at least one example of the present disclosure. With additional reference to FIG. 2, the sensor detection system 100 may generally include a plurality of sensors 102, one or more communication hubs 104, and one or more base stations or gateways 106. The sensors 102 may be located within a predetermined area (e.g., floor, room, etc.) within a building 101 based on the intended application and may be configured to communicate with an associated communication hub 104 (e.g., which may also be disposed on the same floor and/or an adjacent floor). According to one example, the sensors 102 may be wireless sensors, e.g., configured to communicate (e.g., transmit and/or receive) with the communication hubs 104 via a short-range wireless communication protocol. Examples of short-range wireless communications include, but are not limited to, Bluetooth, Near Field Communication, Ultra-Wide Band, WiFi, ZigBee, wireless personal area networks (WPAN) and wireless local area networks (WLAN). The use of a short-range wireless communication protocol may reduce the power consumption of the sensors 102, thereby enhancing the battery life of the sensors 102. In at least one example, the sensor 102 includes a water detection sensor, though it should be appreciated that one or more of the sensors 102 may include any known sensor such as, but not limited to, temperature sensors, humidity sensors, proximity sensors, smoke sensors, carbon monoxide sensors, or the like.

The communication hubs 104 may communicate with the base station 106 via a short-range wireless communication protocol and/or a long-range wireless communication protocol. Non-limiting examples of long-range wireless communication protocols include local area network (LAN), wide area network (WAN), metropolitan area network (MAN), or a worldwide area network (WWAN—the Internet). The use of a long-range wireless communication protocol may enable the communication hubs 104 to communicate with the base station 106 over longer distances. It should be appreciated that one or more of the sensors 102 and/or the communication hubs 104 may be configured to transmit signals over a wired connection and/or may be battery powered and/or hardwired to a power source (e.g., an alternating current power source).

The base station 106 may communicate information (e.g., notifications) 108 to users using one or more wired communications interfaces (universal serial bus (USB), IEEE 802.3 (Ethernet), etc.), one or more wireless communications interfaces (IEEE 802.11 (WiFi), Bluetooth®, ZigBee, Cellular GSM, Cellular CDMA, etc.), or any combination thereof. The notifications 108 may include email messages, text messages, phone messages, and/or visual or auditory notifications (e.g., warning lights, warning alarms, etc.), for example, on a computer system. In some examples, the notifications 108 may be triggered by a sensor 102 detecting of one or more events within the building 101. For example, the notifications 108 may be triggered by a water sensor 102 detecting a water leak. The notification 108 may include the location within the building 101 associated with where the water leak sensor was initially installed/secured. The location may correspond to a predetermined area or region within the building 101 and/or may correspond to a specific room and/or location within a room.

The system 100 may optionally include one or more valve controllers 110 which may receive a signal from any component within the system 100 (e.g., from a sensor 102, hub 104, and/or a base station 106) that causes a valve to actuate. In some examples, the valve controller 110 may be configured to close one or more water valves. The valve controller 110 may be configured to identify the location associated with the water sensor 102 that generated the leak detection signal and may close one or more valves depending on the location of the water sensor 102 that generated the leak detection signal. Alternatively (or in addition), the valve controller 110 may close one or more main water valves associated with the building 101.

Of course, the above description is provided for exemplary purposes only, and the sensor 102 may detect various conditions and generate messages in any manner known to those skilled in the art. By way of a non-limiting example, the sensor 102 may communicate directly with a building management system and/or valve controller 110.

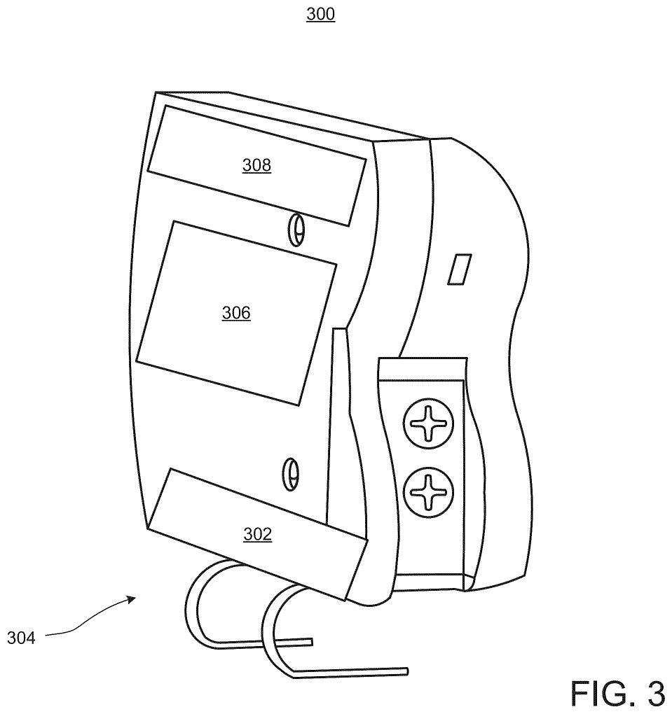

Turning now to FIG. 3, one example of a sensor 300 consistent with FIG. 1 is generally illustrated. The sensor 300 may include a water detection sensor configured to detect the presence of water. The sensor 300 may include any water detection circuitry 302 for detecting the presence of water know to those skilled in the art. In the illustrated example, the water detection circuitry 302 may include one or more probes or the like 304. The probes 304 may be configured to be disposed proximate to a surface to be monitored, e.g., the floor, a containment area (such as a pan), or the like. The sensor 300 may include a power source 306 (e.g., one or more batteries, inductive charging circuit, or the like) and/or may be configured to be hardwired to an external power source (e.g., an alternating current source).

The sensor 300 may additionally include communication circuitry 308 to transmit at least one output signal (e.g., to the hub 104 and/or base stations 106) that includes information indicative of a water detection event and a location of the sensor 300. The information representative of the location of the sensor 300 may include a sensor identification which may be correlated with a location of the sensor 300 within the building 101, for example, by the hub 104, base station 106, and/or management system (e.g., database) associated with the sensor detection system 100. The sensor identification may include any data configured to uniquely identify the sensor 300. The communication circuitry 308 also be configured to receive signals (e.g., from the hub 104 and/or base stations 106). The received signals may be used to verify the operational status of the sensor 300 (e.g., if the battery state is low, whether the sensor 300 is turned on, and/or if the sensor 300 is functional). The communication circuitry 308 may include any communication circuitry (e.g., transceiver circuitry) known to those skilled the art.

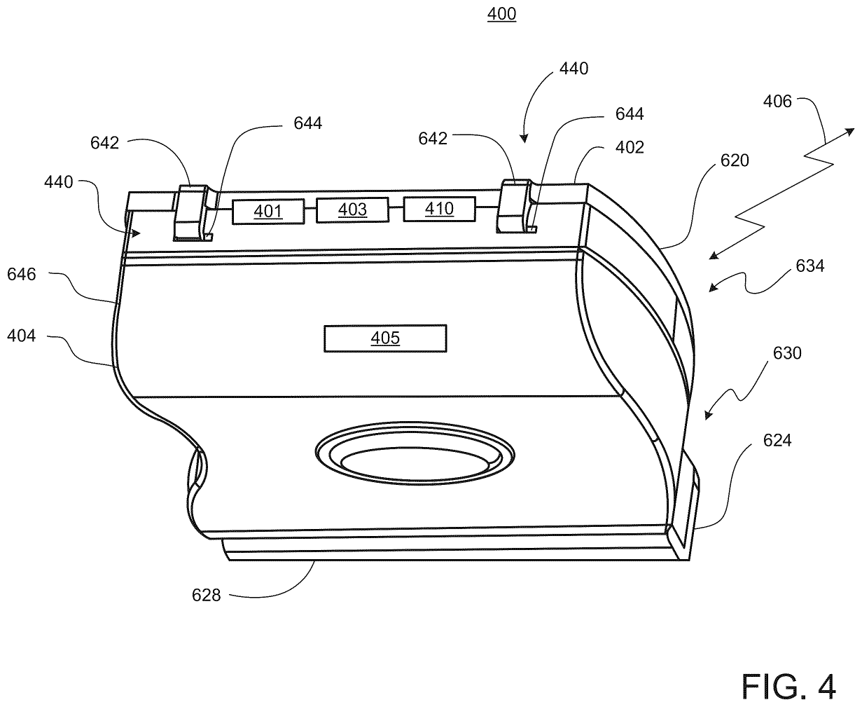

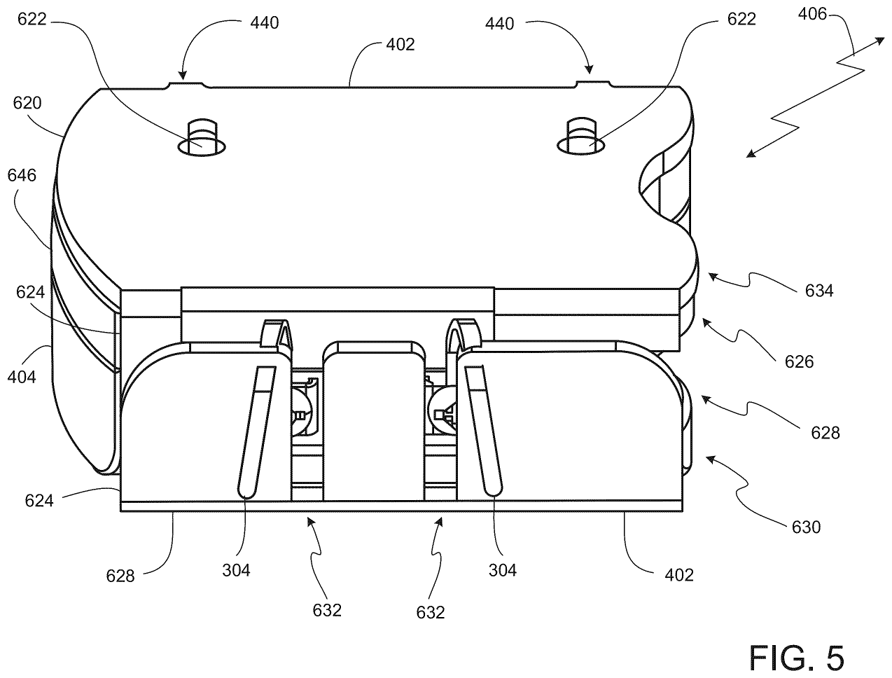

Turning now to FIGS. 4-5, one example of a sensor location verification system 400 is generally illustrated. In particular, FIG. 4 is a top, front, perspective view of the assembled sensor location verification system 400 and FIG. 5 is a bottom, rear perspective view of the assembled sensor location verification system 400. The sensor location verification system 400 includes a sensor locator 402 and a sensor 404. As explained herein, the sensor locator 402 is configured to be coupled, mounted, or otherwise secured to a specific location within a building 101 (e.g., a wall, floor, containment compartment, or the like) and the sensor 404 is configured to be removably coupled, mounted, or otherwise secured to the sensor locator 402. The sensor locator 402 and the sensor 404 may be paired together to form a sensor/locator pairing, for example, that corresponds to a specific location within the building 101 as described herein.

The sensor location verification system 400 may include one or more pairing verification circuits 401 and optionally one or more communication circuits 403. The pairing verification circuit 401 may be configured to generate one or more pairing notifications 406 indicative of the status of the sensor/locator pairing. The pairing verification circuit 401 may be located entirely within the sensor 404, entirely within the sensor locator 402, or distributed between the sensor 404 and the sensor locator 402.

The pairing verification circuit 401 may include any known circuitry configured to generate one or more pairing notifications 406 indicative of the status of the sensor/locator pairing. The pairing verification circuit 401 may include mechanical circuitry (e.g., switches that are actuated by mechanical means), analogue circuitry, and/or digital circuitry that generates a pairing notification 406 based, at least in part, on an incorrect sensor/locator pairing (e.g., triggered/actuated upon securing and/or removing the sensor 404 from the sensor locator 402). In at least one example, the pairing verification circuit 401 may include a normally closed circuit that generates a pairing notification 406 based, at least in part, on an incorrect sensor/locator pairing. Put another way, the pairing verification circuit 401 may be closed when the correct sensor 404 is coupled to its associated sensor locator 402. As used herein, normally closed is intended to mean that current/voltage is generally prevented from flowing through the pairing verification circuit 401 in response to a correct sensor/locator pairing. In the event that the sensor 404 is disconnected from its associated sensor locator 402 and/or a sensor 404 that is not paired with the sensor locator 402 is coupled to the sensor locator 402, then the pairing verification circuit 401 may cause a pairing notification 406 to be generated. One benefit to a normally closed pairing verification circuit 401 is that the pairing verification circuit 401 generally does not consume any power when correctly paired. Reducing power consumption may be an important consideration particularly when the pairing verification circuit 401 is used in battery-powered applications.

The communication circuits 403 may be configured to transmit the pairing notifications 406 and/or transmit one or more signals generated by the sensor circuitry 405 associated with the sensor 404 (e.g., a water detection signal). The communication circuit 403 may also be configured to receive one or more signals, for example, from a communication hub 104, base station 106, or the like (e.g., to perform testing, verify operational status, or the like). The communication circuit 403 may be located entirely within the sensor 404, entirely within the sensor locator 402, or distributed between the sensor 404 and the sensor locator 402. As noted herein, the communication circuit 403 may include long-range and/or short-range wired and/or wireless communication protocols.

The pairing notification 406 may indicate whether the correct sensor 404 is coupled to the correct sensor locator 402 associated with the sensor/locator pairing. For example, one or more pairing notifications 406 may be generated in response to the sensor 404 being removed from the associated sensor locator 402. Alternatively (or in addition), one or more pairing notifications 406 may be generated in response to the correct sensor 404 being coupled to the associated sensor locator 402. Alternatively (or in addition), one or more pairing notifications 406 may be generated in response to the incorrect sensor 404 being coupled to the associated sensor locator 402. Alternatively (or in addition), one or more pairing notifications 406 may be generated automatically based on predetermined time intervals (e.g., once a week, once a month, etc.) and/or external events (cleaning schedules, maintenance events, etc.).

The pairing notification 406 may include one or more remote pairing notifications that may be included in a signal that is transmitted to a communication hub 104 and/or a base station 106. The remote pairing notification may include data representative of the pairing status (e.g., a binary one if the pairing status is correct and/or a binary zero if the pairing status is incorrect). The remote pairing notification may optionally include data representative of the location of the sensor/locator pairing, data representative of the location of the sensor locator 402, identification data associated with the sensor locator 402, identification data associated with a sensor 404 that is being coupled to a sensor locator 402, and/or identification data associated with the sensor 404 that is being removed from a sensor locator 402. The remote pairing notification may be generated by the sensor locator 402 and/or the sensor 404 and may be transmitted continuously, periodically, or based on predefined events (e.g., coupling and/or removal of a sensor 404 from a sensor locator 402).

Alternatively (or in addition), the pairing notification 406 may include one or more local pairing notifications. Examples of local pairing notifications include, but are not limited to, visual indicia, auditory indicia, and/or haptic indicia. Visual pairing notifications may include one or more status lights representative of the pairing status (e.g., a green visual notification if the pairing status is correct and/or a red visual notification if the pairing status is incorrect). Auditory pairing notifications may include one or more sounds representative of the pairing status (e.g., a confirmatory sound if the pairing status is correct and/or an alarm sound if the pairing status is incorrect). Haptic indicia may include positive vibratory feedback if the pairing status is correct and/or negative vibratory feedback if the pairing status is incorrect (positive and negative vibratory feedback may correspond to different vibratory feedbacks such as patterns, strength, and/or lengths of the vibratory feedback). The local pairing notification may be generated by the sensor locator 402 and/or the sensor 404 and may be generated continuously, periodically, or based on predefined events (e.g., coupling and/or removal of a sensor 404 from a sensor locator 402).

The sensor location verification system 400 may optionally include identification indicia 410 that allows a user to determine which sensor 404 corresponds to which sensor locator 402 of a sensor/locator pairing after the sensor 404 has been removed from the sensor locator 402. For example, the identification indicia 410 may include visual indicia such as, but not limited to, alpha-numeric characters, various patterns, colors, lights, or the like. By way of a non-limiting example, the identification indicia 410 an alpha-numeric code on both the sensor locator 402 and sensor 404. The identification indicia 410 (e.g., alpha-numeric code) may also be used to uniquely the location of the sensor/locator pairing. The identification indicia 410 may optionally provide a visual and/or audible confirmation when the correct sensor 404 is coupled to the corresponding sensor locator 402 of the sensor/locator pairing. For example, the identification indicia 410 may include a light that confirms the correct sensor/locator pairing. Alternatively (or in addition), the identification indicia 410 may a light indicating an incorrect correct sensor/locator pairing (e.g., that the incorrect sensor 404 has been coupled to a sensor locator 402).

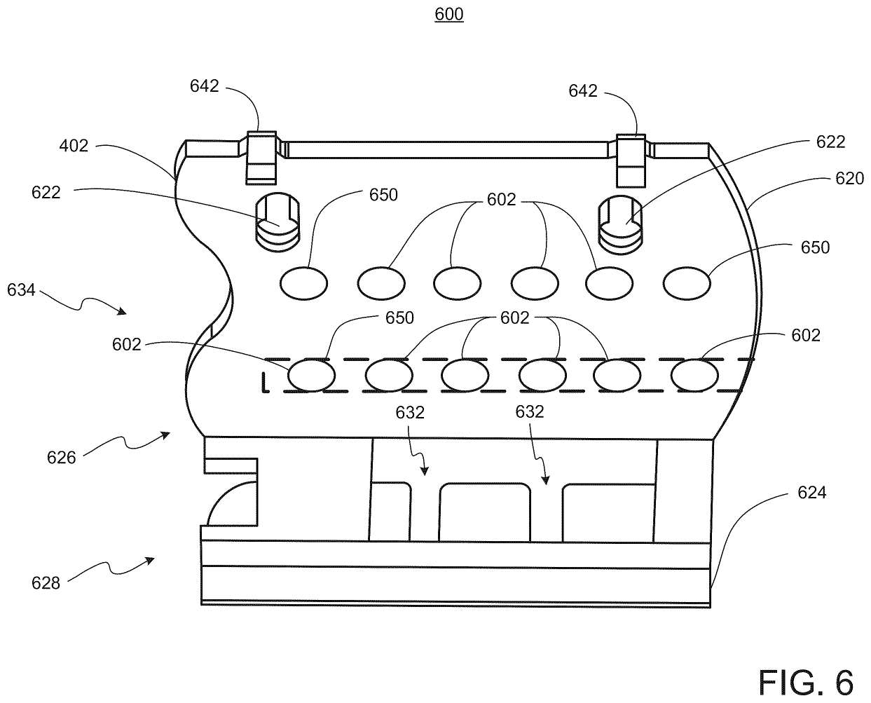

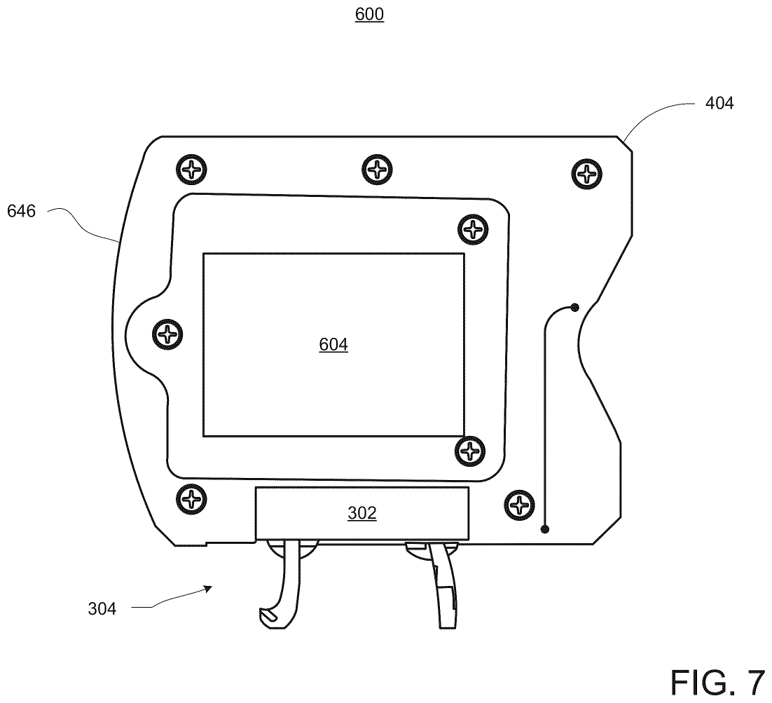

One example of a pairing verification circuit 401 is generally illustrated in FIGS. 6-7. In particular, the pairing verification circuit 600 may be formed by a combination of the sensor locator 402 and the sensor 404 and may include one or more magnets 602 and one or more magnetic sensors 604 (e.g., Hall effect sensors). When the sensor 404 is coupled to the corresponding sensor locator 402 of a sensor/locator pairing, the magnets 602 and/or magnetic sensors 604 associated with the paired sensor 404 and corresponding sensor locator 402 may form a unique magnet/sensor pattern which corresponds to the sensor/locator pairing. The unique magnet/sensor pattern may be used to set/define the sensor/locator pairing to a specific location within a building. It should be appreciated that the unique magnet/sensor pattern may be one of a plurality and/or set of predefined magnet/sensor patterns (e.g., but not limited to, 8 magnet/sensor patterns, 16 magnet/sensor patterns, 128 magnet/sensor patterns, or the like). The magnet/sensor patterns may be based on the number of magnets 602, the number of magnetic sensors 604, the location of the magnets 602, the location of the magnetic sensors 604, and/or the strength of the resulting magnetic fields. For example, the magnet/sensor patterns may include a single magnet and a single magnetic sensor, multiple magnets and a single magnetic sensor, a single magnet and multiple magnetic sensors, and/or multiple magnets and multiple magnetic sensors.

In the illustrated example, the magnets 602 may be disposed in the sensor locator 402 and the magnetic sensors 604 may be located in the sensor 404; however, the magnets 602 may be disposed in the sensor 404 and the magnetic sensors 604 may be located in the sensor locator 402 and/or magnets 602 and magnetic sensors 604 may be located in both the sensor locator 402 and/or sensors 404.

The magnet/sensor pattern may be user definable. For example, all or a portion of the magnet/sensor pattern may be set by the user during installation of the sensor location verification system 400. For example, the user may set the magnet/sensor pattern for the sensor locator 402, the sensor 404, or both the sensor locator 402 as well as the sensor 404. A system in which the magnet/sensor pattern is factory set for the sensor locator 402 and user set for the sensor 404 may allow for the sensor 404 to be replaced/retrofitted to a previously installed sensor location verification system 400 without having to replace the sensor locator 402 and/or reprogram the monitoring system, while also minimizing the likelihood that sensor locator 402. Alternatively (or in addition), the magnet/sensor pattern may be factory preset. As such, a sensor locator 402 having a specific magnet/sensor pattern may need to be used with a specific sensor 404. Such an arrangement may minimize the possibility of the same magnet/sensor patterns being used for two or more sensor location verification systems 400.

As noted herein, the sensor locator 402 and sensor 404 may be configured to be removably coupled together. With reference to FIGS. 4-7, one example illustrating a removable connection system for removably coupled the sensor locator 402 and sensor 404 is generally illustrated. The sensor locator 402 may include a mounting plate 620 (see, e.g., FIG. 6). The mounting plate 620 may be configured to be secured to a support surface (e.g., a wall) in any manner known to those skilled in the art. In the illustrated example, the mounting plate 620 may include one or more mounting apertures 622, for example, configured to receive one or more screws, bolts, nails, rivets, or the like. Alternatively (or in addition), the mounting plate 620 may be secured to the support surface using an adhesive, hook and loop fastener, or the like. In the illustrated example, the mounting plate 620 may be configured to extend generally vertically when the sensor locator 402 is mounted to a wall. The mounting plate 620 may have a height that generally corresponds to the height of the sensor 404, for example, as generally illustrated in FIGS. 4-5.

The sensor locator 402 may optionally include one or more sidewalls 624, for example, extending from the mounting plate 620. The sidewalls 624 may be configured to receive and/or support a portion of the sensor 404. For example, the sidewall 624 may extend from a bottom region 626 (see, e.g., FIGS. 4 and 5) of the mounting plate 620 and may form a base 628 configured to support a bottom region 630 of the sensor 404. The base 628 may optionally include one or more slots, grooves, channels and/or the like (hereinafter referred to collectively as a sensor aperture 632, best seen in FIGS. 5 and 6) configured to receive a portion of the sensor 404 such as, but not limited to, a portion of the water detection circuitry 302. In the illustrated example, the sensor aperture 632 may be configured to receive a portion of the probes 304 such that the probes 304 may be exposed proximate to the surface on which the water leak is to be detected. Of course, the base 628 is only one example of a sidewall 624 and the sensor locator 402 may include additional and/or alternative sidewalls 624. In at least one example, the mounting plate 620 and the sidewall(s) 624 may define a sensor cavity 634 configured to receive and/or support at least a portion of the sensor 404.

The sensor locator 402 may include one or more retainers 440 (see, e.g., FIG. 4) to removably secure the sensor 404 to the sensor locator 402. The retainers 440 may include any known means for removably securing the sensor 404 to the sensor locator 402. For example, the retainer 440 may be formed, at least in part, by the sensor cavity 634. Alternatively (or in addition), the retainer 440 may include one or more resiliently deformable tabs or prongs 642 (see, e.g., FIG. 6) extending from the mounting plate 620 and/or a sidewall 624 configured to be receive in one or more corresponding grooves or cavities 644 (see, e.g., FIG. 4) formed in the housing 646 of the sensor 404. Of course, the arrangement of the resiliently deformable tabs or prongs 642 and cavities 644 may be switched. Alternatively (or in addition), the retainer 440 may be formed by a hook and loop fastener. Alternatively (or in addition), the retainer 440 may be formed by one or more magnetic connections (which may be the same as, or different than, the magnets 602 used to in the pairing verification circuit 600).

As noted above, the sensor locator 402 may include one or more magnets 602. The sensor locator 402 may include a plurality of magnet mounts (e.g., cavities, recesses, or the like) 650 (see, e.g., FIG. 6) sized and shaped to at least partially receive one or more magnets 602. The magnet mounts 650 may be part of the mounting plate 620 and/or sidewall 624. The magnet mounts 650 may be configured to allow the magnet/sensor pattern to be user definable. For example, the magnet mounts 650 may allow the user to place one or more magnets 602 at specific locations relative to the sensor locator 402 to create a specific magnet/sensor pattern. In one example, a single magnet mount 650 may allow a magnet 602 to be arranged at plurality of locations and/or allow a plurality of magnets 602 to be secured to the magnet mount 650 at a plurality of locations. For example, the magnet mount 650 may include a groove or channel having a plurality of predefined locations. Alternatively (or in addition), the sensor locator 402 may include a plurality of magnet mounts 650, each configured to receive only a single magnet 602. The selection of the magnets 602 within the magnet mounting location(s) 650 may be based, for example, on the location of the magnet sensor(s) 604 (which may be secured to the sensor 404). Alternatively (or in addition), the magnet mounts 650 may allow the user to select magnets 602 having different magnetic fields or strengths. The configuration of the magnet mounts 650 may also be factory preset to correspond to a factory preset magnet/sensor pattern 606 (e.g., determined when manufacturing the sensor locator 402).

As noted herein, the sensor 404 may include one more magnetic sensors 604 (see, e.g., FIG. 7). The magnetic sensors 604 may be configured, for example, to allow current/voltage to flow through a circuit when the magnet/sensor pattern does not match. When the magnet/sensor pattern does match, the magnetic sensors 604 may be configured to generally prevent current/voltage from flowing, thereby minimizing power consumption. The magnetic sensors 604 may therefore form part of an electrical circuit. In some examples, the magnetic sensors 604 may be user definable (e.g., the user may install one or more magnetic sensors 604 at one or more predetermined locations within the electrical circuit. Alternatively, the magnetic sensors 604 may be factory preset.

Of course, it should be appreciated that the sensor 404 may include one or more magnet mounts 650 and/or that the sensor locator 402 may include one or more magnetic sensors 604.

In the illustrated examples, the pairing verification circuit 600 has been primarily described having one or more magnets 602 and one or more magnetic sensors 604 (e.g., Hall effect sensors). It should be appreciated, however, that a pairing verification circuit consistent with the present disclosure may include any known circuit for verifying the sensor/locator pairing. To this end, a pairing verification circuit consistent with the present disclosure may include, but is not limited to, current or voltage detection circuitry (e.g., wherein the pairing verification circuit verifies the sensor/locator pairing based on a unique current and/or voltage), light sensors such as, but not limited to, one or more cameras, optical scanners (e.g., barcode readers) and/or Quick response (QR) code circuits (e.g., wherein the pairing verification circuit verifies the sensor/locator pairing based on a light pattern/frequency using one or more cameras), and/or RF ID circuits (e.g., wherein the pairing verification circuit verifies the sensor/locator pairing based on a RFID tag and RFID reader). In some examples, the QR code or bar code could include a sticker attached to wall and the sensor 402 may be provided with one or more cameras or scanners.

The term substantially, as generally referred to herein, refers to a degree of precision within acceptable tolerance that accounts for and reflects minor real-world variation due to material composition, material defects, and/or limitations in manufacturing processes. Such variation may therefore be said to achieve largely, but not necessarily wholly, the target/nominal characteristic. To provide one non-limiting numerical example to quantify “substantially,” such a modifier is intended to include minor variation that can cause a deviation of up to and including ±10% from a particular stated quality/characteristic unless otherwise provided by the present disclosure.

The term “coupled” as used herein refers to any connection, coupling, link or the like between elements/components. In contrast, directly coupled refers to two elements in contact with each other in a manner that does not include an intermediate element/component disposed therebetween.

The use of the terms “first,” “second,” and “third” when referring to elements herein are for purposes of clarity and distinguishing between elements, and not for purposes of limitation. Likewise, like numerals are utilized to reference like elements/components between figures.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. It will be appreciated by a person skilled in the art that any smart drain system described herein may embody any one or more of the features contained herein and that the features may be used in any particular combination or sub-combination. Modifications and substitutions by one of ordinary skill in the art are considered to be within the scope of the present disclosure, which is not to be limited except by the claims.

What is claimed is:

1. A water sensor location verification system comprising:
a water sensor configured to generate one or more signals indicative of a presence of water;
a sensor locator, the sensor locator configured to be coupled to a support surface and configured to be removably coupled to the water sensor to form a sensor/locator pairing; and
a pairing verification circuit configured to generate a pairing notification indicative of a status of the sensor/locator pairing.

2. The water sensor location verification system of claim 1, wherein the pairing verification circuit comprises a normally closed circuit.

3. The water sensor location verification system of claim 1, wherein the pairing verification circuit comprises one or more magnets coupled to one of the water sensor or the sensor locator and one or more magnet sensors coupled to the other of the water sensor or the sensor locator.

4. The water sensor location verification system of claim 3, wherein the magnetic sensor comprises a Hall effect sensor.

5. The water sensor location verification system of claim 3, wherein the pairing verification circuit is configured to determine the status of the sensor/locator pairing based, at least in part, on the presence of the magnet.

6. The water sensor location verification system of claim 3, wherein the pairing verification circuit is configured to determine the status of the sensor/locator pairing based, at least in part, on a strength of a magnetic field detected by the magnetic sensor.

7. The water sensor location verification system of claim 1, wherein the pairing verification circuit comprises one or more magnets coupled to the sensor locator and one or more magnet sensors coupled to the water sensor.

8. The water sensor location verification system of claim 7, wherein the one or more magnets coupled to the sensor locator are factory preset.

9. The water sensor location verification system of claim 7, wherein the one or more magnets coupled to the sensor locator are user definable.

10. The water sensor location verification system of claim 7, wherein the sensor locator includes a mounting plate configured to be secured to the support surface.

11. The water sensor location verification system of claim 10, wherein the mounting plate includes one or more mounting apertures configured to receive one or more fasteners to secure the sensor locator to the support surface.

12. The water sensor location verification system of claim 10, wherein the sensor locator further includes at least one sidewall extending outwardly from a bottom region of the mounting plate, the at least one sidewall defining a base configured to support the water sensor.

13. The water sensor location verification system of claim 12, wherein the water sensor includes one or more water detection probes for the detection of the presence of water, and wherein the base further includes one or more sensor apertures configured to receive a portion of the one or more water detection probes when the water sensor is coupled to the sensor locator.

14. The water sensor location verification system of claim 10, wherein the one or more magnets are coupled to the mounting plate.

15. The water sensor location verification system of claim 1, wherein the pairing verification circuit comprises a plurality of magnets coupled to one of the water sensor or the sensor locator and one or more magnet sensors coupled to the other of the water sensor or the sensor locator.

16. The water sensor location verification system of claim 1, wherein the pairing verification circuit comprises a plurality of magnets coupled to one of the water sensor or the sensor locator and a plurality of magnet sensors coupled to the other of the water sensor or the sensor locator, wherein each magnet corresponds to a single magnetic sensor when the water sensor is coupled to the sensor locator.

17. The water sensor location verification system of claim 1, further comprising communication circuitry to transmit a signal including data representative to the pairing notification.

18. The water sensor location verification system of claim 17, wherein the signal further includes data representative to a location of the sensor/locator pairing.

19. The water sensor location verification system of claim 1, wherein at the pairing notification includes a local pairing notification configured to allow a user to determine the status of the sensor/locator pairing.

20. A water sensor configured to be removably coupled to sensor locator to form a sensor/locator pairing, the water sensor comprising:
circuitry configured to generate one or more signals indicative of a presence of water;
a pairing verification circuit comprising one or more magnet sensors configured to detect one or more magnet associated with the sensor locator, the paring verification circuit configured to generate a pairing notification indicative of a status of the sensor/locator pairing based on, at least in part, the detection of the one or more magnets, wherein the pairing verification circuit is a normally closed circuit.

21. The water sensor of claim 20, wherein the magnetic sensor comprises a Hall effect sensor.

22. The water sensor claim 20, wherein the pairing verification circuit is configured to determine the status of the sensor/locator pairing based, at least in part, on the presence of the one or more magnets.

23. The water sensor of claim 20, wherein the pairing verification circuit is configured to determine the status of the sensor/locator pairing based, at least in part, on a strength of a magnetic field detected by the one or more magnetic sensors.

24. The water sensor of claim 20, further comprising communication circuitry to transmit a signal including data representative to the pairing notification.

25. The water sensor of claim 24, wherein the signal further includes data representative to a location of the sensor/locator pairing.

26. The water sensor location verification system of claim 20, wherein at the pairing notification includes a local pairing notification configured to allow a user to determine the status of the sensor/locator pairing.
